(19) United States
(12) Patent Application Publication
(10) Pub. No.: US 2026/0002982 A1
(43) Pub. Date: Jan. 1, 2026

(54) METHODS AND APPARATUSES FOR TESTING MULTI-DIE PACKAGE INTER-CONNECT LINKS

(71) Applicant: Intel Corporation, Santa Clara, CA (US)

(72) Inventors: Rakesh KANDULA, Bangalore (IN); Sriram VENKATESAN, Fremont, CA (US); Jeffrey SORIANO, El Dorado Hills, CA (US); Deep BAROT, Mumbai (IN); Takeshi NAKAZAWA, Phoenix, AZ (US)

(21) Appl. No.: 18/757,351

(22) Filed: Jun. 27, 2024

(51) Int. Cl. G01R 31/28

(52) U.S. Cl. CPC G01R 31/2853; G01R 31/2896

(57) ABSTRACT

In some embodiments, techniques for testing die to die interconnect links are provided.

### TECHNICAL FIELD

Embodiments of the invention relate to the field of integrated circuits and more specifically, to the field of testing multi-die interconnect links.

### BRIEF DESCRIPTION OF THE DRAWINGS

The disclosure may best be understood by referring to the following description and accompanying drawings that are used to illustrate embodiments of the invention. In the drawings:

FIG. 1 is a side view diagram showing a multi chip integrated circuit (IC) package 100 in accordance with some embodiments.

FIG. 2 is a schematic diagram showing a lane in a three-dimensional link in accordance with some embodiments.

FIG. 3A is a flow diagram illustrating a routine for performing Tx:Rx path tests in accordance with some embodiments.

FIG. 3B is a flow diagram showing a routine for performing Tx cell, Rx cell and Tx:Rx cell tests in accordance with some embodiments.

FIG. 3C is a flow diagram showing a routine for performing a common Tx cell to multiple Rx cell tests in accordance with some embodiments.

FIG. 3D is a flow diagram showing a routine for performing a multiple Tx cell to common Rx cell defect detection test in accordance with some embodiments.

FIG. 3E is a flow diagram showing a routine for testing a multi-die package as it is being assembled in accordance with some embodiments.

FIG. 4 is a schematic diagram showing a single Tx cell to Rx cell interconnect path in accordance with some embodiments.

FIG. 5 illustrates an example computing system in accordance with some embodiments.

### DETAILED DESCRIPTION

Multi-die integrated circuit (IC) packages such as so-called 3D packages have two or more dies (or chips) mounted atop one another in a stack configuration. For example, in some embodiments, they may use bonding techniques such as hybrid bonding interconnection (HBI) techniques to bond contacts from a lower surface of one die to an upper surface of another. Such packages can have multiple dies (e.g., 2 or more) coupled together in a stack. Among other things, the multi-chip stacks can serve to improve inter-chip latency and also reduce required form factors as the dies are stacked one atop the other. For example, a multi-die stack (or module) may include a processing die with multiple memory dies stacked above (or below) it.

A three-dimensional configuration can facilitate shorter interconnect pathways, improving faster memory read and write operations. For example, processor architects including artificial intelligence processing system designers desire an ability to leverage increased on-package memory to improve latency, bandwidth, power, cost and reliability requirements in order to meet a diverse range of system needs. Accordingly, improved multi-die stacking and Memory cube architectures are being developed. In order to make such stacking techniques feasible, however, new D2D (die-to-die) testing schemes are desired to allow for acceptable packaging costs, time, and yield. Accordingly, in some embodiments, testing methods and apparatuses are provided for testing D2D links in a multi-die package.

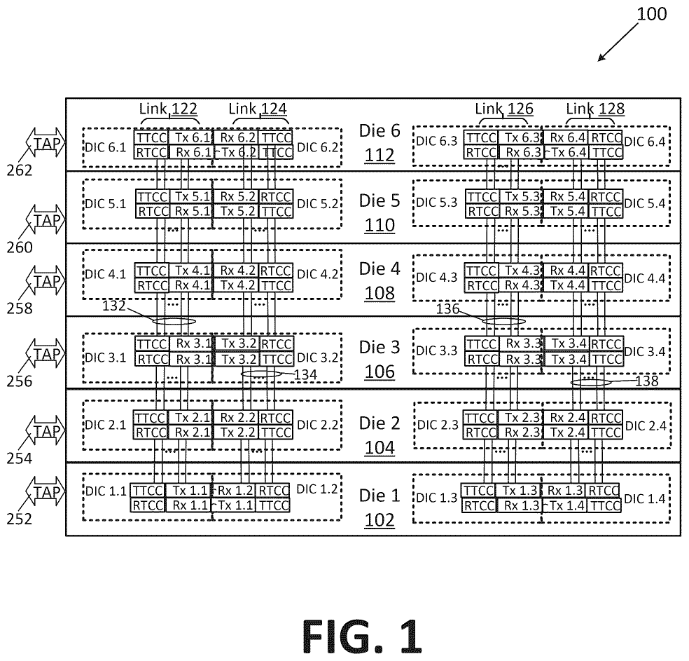

FIG. 1 is a side view diagram showing a multi chip integrated circuit (IC) package 100 in accordance with some embodiments. The depicted multi-die package has six separate dies (also known as tiles or chiplets) 102, 104, 106, 108, 110, and 112 (Die 1 through Die 6, respectively) mounted one on another in a stack configuration as shown. For example, die 102 may be a processor chip while the other five dies (104-112) are memory dies such as high or extreme bandwidth memory (HBM, XBM) mounted together atop the processor die 102 in a stack formation, e.g., using a hybrid bonding interconnect (HBI) technique. However, it should be appreciated that each of the dies may be implemented with any die type (e.g., structure, process) or functionality such as a system on chip (SoC), graphics processing unit (GPU), input/output (IO) extension, applications processing unit (APU), high-performance compute, accelerator, artificial intelligence (AI), memory, and the like. Moreover, while 6 dies are shown, any number of dies could be employed, depending on design objectives and constraints.

IC package 100 has multi-point access, die-to-die (D2D) links including links 122, 124, 126, and 128. A link may convey data in one or more directions. For example, one or more of the links may convey data in an upward direction from Die 1 to Die 6, downward in a direction from Die 6 to Die 1, or both upward and downward, depending on how they are configured.

(Note that the links are shown as being symmetrical, but in some embodiments, there may be more or less links for transferring bits in one direction, another direction, or in multiple directions, and there may be more or less lanes within the different links. Likewise, while each die in the depicted example has a connection to each of the links, in some embodiments, some of the dies may not be connected to all of the links or all of the lanes in a link. Also, the term, “data” is used generally to refer to information conveyed through bits over the link lanes, but it should be appreciated that any given lane may be used to convey data corresponding to any type of information such as address information, control information, error correction information, read data, write data, packet data, etc. Moreover, it should be appreciated that for convenience, and ease of understanding, the relative terms: top, bottom, up and down may be used but should not be construed to refer to any absolute position or direction. For example, Die 1 may be referred to as a bottom die and Die 6 as a top die but depending on one's perspective, these labels could be switched, or different terms such as right and left could be used. Similarly, “up,” “upward”, “down”, or “downward” may be used to describe relative interconnect path directions. For example, a path from Die 1 to Die 6 may be an upward path, and from Die 6 to Die 1 may be a downward path. It should be appreciated, however, that these directional terms are relative and should not be otherwise construed.)

Each link (122, 124, 126, 128) has an associated cluster of lanes (132, 134, 136, 138), respectively, along with a plurality of die interconnect circuits (DICs) that are coupled with the lane clusters. For example, link 122 has lanes 132 and DICs 1.1, 2.1, 3.1, 4.1, 5.1, and 6.1 coupled with lane cluster 132. The lane clusters may include any suitable number of lanes (e.g., 16, 64, 100, 250, 500, or even more), and the number of lanes in each cluster may or may not be the same.

A die interconnect circuit (DIC) communicatively couples its die with some or all of the other dies in its associated link. Each DIC in the depicted embodiment has both receive and transmit circuit blocks coupled with the lanes of the link, which allows for data to be conveyed in a link from any transmitter block in one die to any receiver block in another die on the link. However, in some embodiments, a link may have some of its DICs with only one transmitter block or only one receiver block, as may be the case with unidirectional link applications such as with some multi-chip memory structures. Each lane includes a conductive channel, segmented or continuous, and transmitter and receiver circuit components from the DICs that are coupled to the channel to transmit data in the lane. A channel is a conductive path formed from conductive elements such as contacts, vias, traces, switches, and/or wires within the dies and die packages that transfer data in a lane between a transmitter and a receiver.

In some embodiments, the transmit circuit blocks include an operational transmitter circuit (Tx) and a transmitter test control circuit (TTCC) as indicated in the figure. The operational transmitter circuit (Tx) includes operational transmit control circuitry and transmitter cell circuits (not shown) for transmitting data bits through their associated link. The TTCC controls transmission of test pattern bits through the lanes to test them for defects such as defective or misaligned contact bonds. The transmitter cell circuits (or simply transmitter cells) may include transmitter cell test circuits that may be used by the TTCC to perform local Tx cell tests, testing the operational transmit cell circuitry independent of contact connections with counterpart receiver cell circuits.

Similarly, the receive circuit blocks include an operational receiver circuit (Rx) and a receiver test control circuit (RTCC) as indicated in the figure. The operational receiver circuits (Rx) include operational receive control circuitry and receiver cell circuits (receiver cells, also not shown) for receiving transmitted bits from transmit cells in the same link. The receiver cells may also include receive cell test circuits coupled with the receiver cells for not only performing local Rx cell tests, testing the receiver cells, independent of contact bonds with counterpart transmit cells, but also, to facilitate, in cooperation with an associated TTCC and RTCC, defect detection for a Tx:Rx (Tx-cell to-Rx cell) lane path. When a test is to be performed, the TTCC sends test patterns through the lanes being tested to the receiver test circuits in the lane. The receiver test circuits compare received data with expected data, flagging an error for the lane if the data is different. These results may then be read and made available by the RTCC.

The lane pathways (or channels) function as buses with the transmit circuit blocks (TTCC, Tx) and receive circuit blocks (RTCC, Rx) tri-statably coupled to them, i.e., switchably coupled to them in a tri-stateable manner. In this way, for a given link, data may be conveyed from a transmitter cell (Tx) of one die to one or more receiver cells in different dies on the same link. This may be beneficial in that different links, and even different lanes within a link, can communicate between different transmitter/receiver cell combinations from different dies. For example, with the depicted figure, assuming that Die 1 is a processor chip and the other dies are memory dies, the processor could write to and read from some or all of the different memory dies at the same time, not only facilitating more efficient power and thermal management, but also, allowing for enhanced memory bandwidth.

In some embodiments, the links use single-ended forwarded clock schemes with each link having at least one clock provided from a transmit circuit block to one or more receive circuit blocks for synchronizing data transfers from transmitter cells to receiver cells. In other embodiments, synchronized link clocks may be distributed to the DICs but not necessarily be conveyed from a transmitter, as such, to a receiver, but instead, for example, made available in a link with each cell or operational control circuit having one or more clock gates for controlling particular cell operations. A link may also have one or more side-channel control lines for communicating control information between DICs on a link, e.g., for Tx cell and/or Rx cell access to a lane.

In the depicted embodiment, the dies each have one or more test access ports (TAPs) 252, 254, 256, 258, 260, or 262, as is shown. A TAP may be implemented with any suitable test access interface, custom or in compliance with a known standard for use during a manufacture process and/or in the field for controlling and reading data from the TTCC and RTCC to run defect detection tests on the lanes within the links. In some embodiments, a JTAG (Joint Test Access Group) test port architecture may be employed. (A JTAG interface is an interface used in a chip. Depending on the version of JTAG, two, four, or five pins may be used. The four and five pin interfaces may be designed so that multiple chips within a package can have their JTAG lines daisy-chained together or, as with some two pin interface designs, multiple chips can be connected in a star topology. In either case, an external test system interface for controlling the TAPs in the different DICs need only couple to a single “JTAG port” to have access to multiple dies within a multi-die module, although separate external access interfaces may also be used, as may be the case when assembling dies for a stack. Aspects of any suitable JTAG standard such as IEEE (Institute of Electrical and Electronics Engineers) 1149.1 (for chip access) or IEEE 1838 (single port, multi-chip module access), which builds on test standards such as IEEE 1149.1, IEEE 1500, and other standards may be employed. Alternatively, or in addition to, other test port interface standards may be used such as Serial Wire Debug (SWD).

As will be addressed further below, tests can be run on individual dies, through a single die in a completed package or for two or more dies in a complete stack or even in a partial stack, as it is being assembled.

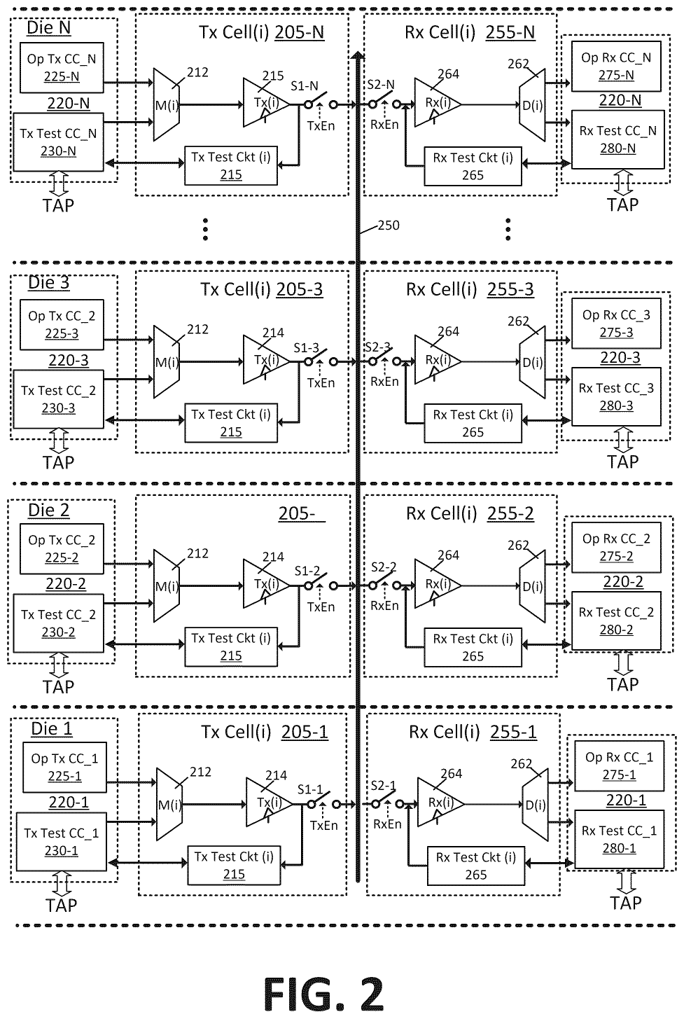

FIG. 2 is a schematic diagram showing a lane in a three-dimensional link in accordance with some embodiments. The link is part of a multi-die stack package having N dies, Die 1 through Die N. The lane includes DICs 220, TX cell circuits (or Tx cells) 205, Rx cell circuits (or Rx cells) 255, and a channel (e.g., conductive path through two or more dies) 250. The DICs are coupled through the Tx and Rx cells 205, 255 to the channel 250.

In the depicted embodiment, the DICs (220-1 through 220-N) have both transmitter and receiver circuit blocks. The transmitter blocks include operational transmitter control circuits (OTCCs) 225 and transmitter test control circuits (TTCCs) 230, and the receiver blocks include operational receiver control circuits (ORCCs) 275 and receiver test control circuits (RTCCs) 280, as is shown.

The Tx cells 205 include a 2:1 mode select multiplexer (also referred to as a switch) 212, a sequential transmitter driver circuit 214, a transmitter cell test circuit 215, and a channel access switch S1, coupled together as shown to an associated OTCC 225, an associated TTCC 230, and to the channel 250 through switch S1. Likewise, the Rx cells 255 include a 1:2 mode select demultiplexer (also referred to as a switch) 262, a sequential receiver driver circuit 264, a receiver cell test circuit 265, and a channel access switch S2, coupled together as shown.

(As used herein, a multiplexer (or “Mux”) is a type of switch that has an output and two or more inputs that may be selectively controlled to be coupled with the output. Likewise, a demultiplexer (or “Dmux”) is a type of switch that has an input and two or more outputs that may be selectively controlled to be coupled with the input. A sequential driver circuit is a circuit that receives digital data at an input and uses one or more clocks to propagate the data from the input out of the sequential driver circuit through an output. A sequential driver circuit may have one or more circuit elements such as buffers, amplifiers, drivers, latches, flip-flops, and/or gates to perform this operation. A sequential driver may be used as a sequential transmitter driver circuit to clock data onto a channel, or it may be used as a sequential receiver driver circuit to receive data from a channel. A flip-flop is a type of latch that is typically clocked off of a clock edge while latches may allow data to pass from input to output while a clock is asserted, high or low. As used herein, however, a latch may be clocked off of a pulse, a clock edge or a sustained clock state, depending on design considerations such as operating frequencies, timing reliability, alignment tolerances, etc.)

During normal operation, data may be transferred from a transmitter cell 205 to one or more receiver cells 255. The multiplexer (or mux) 212 in a Tx cell 205 is controlled to select an associated OTCC 225 and the switch (S1) in the cell is closed. The OTCC 225 may then convey data through the mux 212 and sequential Tx driver 214 onto the channel 250. During this time, one or more Rx cells 255 may be enabled with their switches (S2) and demuxes (262) selected to receive the data from the transmitting Tx cell. The sequential Tx driver circuit 214 and sequential Rx driver circuits 264 for the enabled Rx cells 255 are clocked together in sync with each other. A common clock may be generated from the transmitting OTCC or from a separate clock generator for the link, and the same, or derived, clocks may be used, so long as they are sufficiently synchronized with one another. For example, some of the cells may be delayed by a number of clock cycles even though they are in sync with each other. In addition, with some schemes, different clock frequencies may be applied for the Tx and Rx cells. For example, with some asymmetric double data rate (DDR) methods, the clock frequencies for Rx cells may be one-half of the Tx cell clocks, with their sequential Rx driver circuits latching data on both rising and falling clock edges.

When the Tx and Rx cells, and/or the channel and channel connections, are to be tested, the muxes 212 and demuxes 262 are controlled to select the relevant TTCCs 230 and RTCCs 280. For a Tx cell test, a TTCC 230 causes a test pattern to be transmitted through a cell 205 (i), and the Tx cell test circuit 215 (i) in the cell compares the test pattern with an expected pattern. The Tx cell test circuit essentially tests the Tx side circuitry including the sequential Tx driver for the cell without the Tx cell having to be coupled with the channel. In some embodiments, the TTCC 230 in a DIC conducts these local Tx cell tests for all of the Tx cells (205 (i)) in the DIC and logs the results. The tests for the different cells may be run at the same time or sequentially, in a time multiplexed manner so as to reduce overhead required for test data and signal paths. In addition, tests may be done on the Tx cells of a link in a die apart from those done in other links or other dies, or they may be done together. The TAPs may be used to control the TTCCs and to read the results.

In some embodiments, the Rx test cell circuits 265 may be used for both local testing, testing the Rx cells themselves, apart from Tx:Rx data path tests over the channel, as well as for use in performing Tx:Rx path tests over the channel. For a local Rx cell test, an RTCC 280 causes a test pattern to be transmitted through an Rx cell 255 (i), and the Rx cell test circuit 255 (i) in the cell compares the test pattern with an expected pattern. In this way, the Rx cell test circuit can test the Rx side circuitry including the sequential Rx driver for the cell without the Rx cell having to be coupled with the channel. In some embodiments, the RTCC 280 in a DIC conducts these tests for all of the Rx cells (255 (i)) in the DIC and logs the results. The tests for the different cells may be run at the same time or sequentially, in a time multiplexed manner so as to reduce overhead required for test data and signal paths. In addition, tests may be done on the Rx cells of a link in a die apart from those done in other links or other dies, or they may be done together. The TAPs may be used to control the RTCCs and to read the results.

When Tx:Rx channel tests are to be performed, the involved TTCC(s) and RTCC(s) are initialized to set up timing and expected test patterns. For each Tx:Rx path that is to be tested, a TTCC transmits a test pattern through the Tx cell(s) in the path(s) under test, over the channel and to the Rx cell(s) under test. Timing is coordinated so that the Rx cell test circuit(s) in the cell(s) being tested can meaningfully compare received with expected data. If they are different, the Rx cell test circuit flags a defect for the cell, which is logged by the RTCC. As with the other tests, multiple cells and multiple paths may be tested, at the same time or in a sequential manner, depending on design considerations. With this testing capability, multi-chip modules can be tested and also, dies may be tested alone, or as they are mounted to a stack. Depending on the detected defects, errant components may be deemed to be tolerable, e.g., given available error correction code (ECC) capabilities, or the faulty paths may be bypassed. If not tolerable, or repairable, they may be discarded before the package is finalized, thereby avoiding even more costly losses.

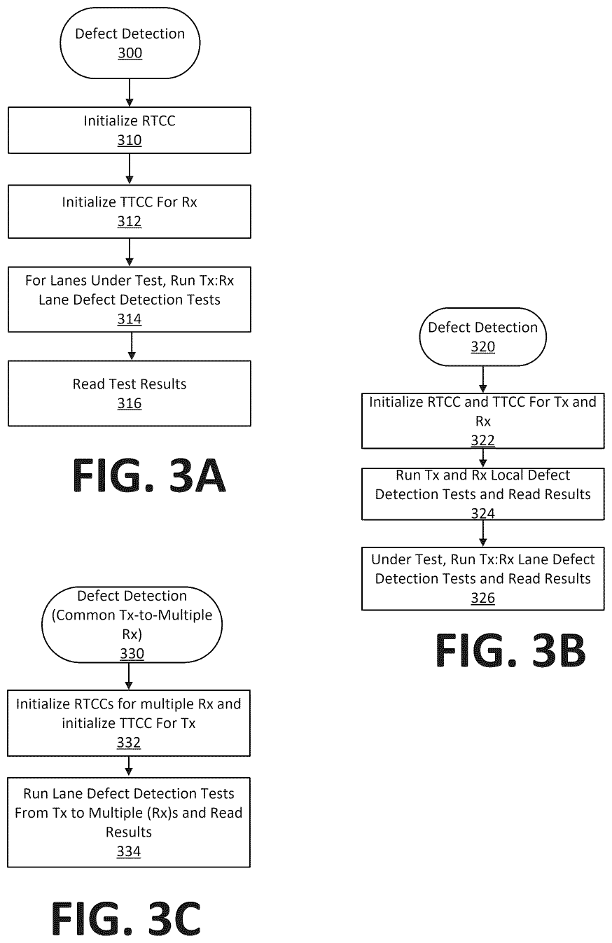

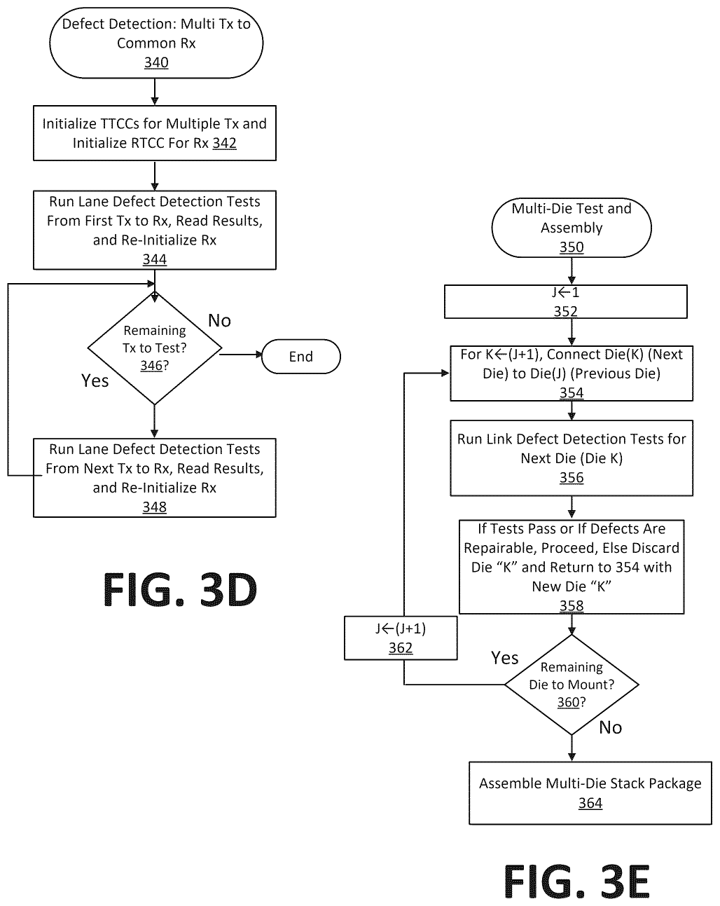

FIG. 3A is a flow diagram illustrating a routine 300 for performing Tx:Rx path tests in accordance with some embodiments. At 310, a receiver test control circuit (RTCC) is initialized, and/or programmed, with test parameters including an expected test pattern or setting for the same, timing parameters and activation parameters. For example, a particular test pattern (e.g., ′11110000 . . . . ; ′1010 . . . , or other) may be used for a particular path, or path type. For example, as multi-die bonding technologies emerge, contact technologies (bumps, hybrid bonding, copper pillar bonding, etc.) change and eventually the defect profiles change, resulting in some cases with a need to use different test patterns. With a programmable test capability, test patterns may be configured for specific contact structures and changed over time for different products or for a given product as it ages. For example, with some contact technologies, a majority of defects may be bridging Faults or wafer Xy misalignment. Different test patterns may be used to detect these defects. Thus, a programmed transmit test pattern may be based on a particular defect profiling scenario. For example, if a part has not significantly aged, a user may use a toggling pattern (e.g., 101010101). On the other hand, if the part is aged, a user may choose to test the lanes using a less-changing pattern such as 11111000001111100000 to effectively ease required impedance characteristics (e.g., reactance parameters) of a given set of paths. As should be appreciated, there may be a variety of different test patterns that can enhance identification of defect characteristics for different die-to-die paths. Timing parameters such as the number of clock cycles to expect or ignore or pattern clocking frequency settings may also be programmed into the RTCC. In addition, initial values may also be set, for example, at comparison inputs to prime a test prior to initiation. Other settings may also be initialized.

At 312, the routine programs the transmitter test control circuit (TTCC) with a suitable expected pattern corresponding to the expected test pattern that is selected for the RTCC. Other settings, or parameters such as pattern lengths (e.g., no. of cycles) and activation settings may also be set.

At 314, the Tx:Rx test(s) is/are conducted. As such, the test patterns are clocked through the paths under test from the transmitter side to the receiver side and once there, compared with the programmed expected pattern. If the patterns sufficiently align with one another, then the path is sound. Otherwise, a defect may be detected. If so, the test may be repeated or another pattern may be employed or a different (e.g., lower) clock frequency may be used to better diagnose the observed defect. For this part, one or more lanes (Tx cell to Rx cell paths) may be tested. In some embodiments, the lanes in a DIC are tested at the same time, and in other embodiments, they are tested sequentially. For the latter, the TTCC and RTCC for affected paths to be tested may sequentially run tests through some or all of their different lanes, with the results saved in the Rx cell test circuits once the tests have completed.

At 316, the routine then reads the test results from the RTCC(s). This may be done, for example, by reading them from a TAP out of corresponding registers in an RTCC or the RTCC may be controlled, for example, to shift the results through from each Rx cell test circuit. This latter approach reduces resources needed to implement an RTCC.

FIG. 3B is a flow diagram showing a routine 320 for performing Tx cell, Rx cell and Tx:Rx cell tests in accordance with some embodiments. At 322, the relevant RTCC(s) and TTCC(s) are initialized such as was described above with regard to FIG. 3A. One difference may be that the controllers are programmed to perform local (self) cell tests along with Tx to Rx cell path tests.

At 324, local Tx cell and Rx cell defect tests are run, and the results are tracked. At 326, the Tx cell to Rx cell defect tests are then run as well. In some embodiments, before they are run but after the local defect tests have been conducted, the controllers (TTCC, RTCC) may be re-initialized or flags in the Tx and/or Rx cell test circuits may be set to save the local results for reconciliation with Tx:Rx path results, or they may be used to skip the full Tx:Rx path tests or to otherwise change them in view of the local test results. For either or both the local and Tx:Rx tests, in response to detected defects, the tests may be repeated, under the same or different conditions. For example, they may be run at slower clock speeds or different patterns may be used to better identify any issues.

FIG. 3C is a flow diagram showing a routine for performing a common Tx cell to multiple Rx cell tests in accordance with some embodiments. For this method, a TTCC from one die sends test patterns onto the channel in order to test pathways to Rx cells from multiple dies together. At 332, the RTCCs with Rx cells under test and the TTCC with cells under test are initialized, as discussed above. With this test approach, multiple Rx cells may access the test pattern from the channel. Accordingly, the test pattern, along with its duration and frequency, should be selected to accommodate the additional load on the channel. The tests are then run, and the results (e.g., number and locations of failed Tx:Rx cell paths are read.

FIG. 3D is a flow diagram showing a routine 340 for performing a multiple Tx cell to common Rx cell defect detection test in accordance with some embodiments. For this method, TTCCs from multiple dies send a test pattern onto the channel to a common Rx cell under test. Unlike with the common Tx to multiple Rx method of FIG. 3C, the test pattern cannot be sent at the same time from all of the Tx cells under test for a given Tx cell (i) since they would conflict with one another on the channel. Accordingly, the separate Tx cell to Rx cell path combinations are run separately. At 332, the RTCCs with Rx cells under test and the TTCC with cells under test are initialized, as discussed above.

At 344, the routine runs the test for a first Tx cell cluster to the Rx cell cluster being tested, reads the results and if necessary, re-initializes the RTCC for the Rx cluster under test. At 346, the routine checks to see if there are additional Tx cell clusters to test. If so, then the routine proceeds to 348 and performs the test for the next Tx cell cluster, reads the results, and re-initializes the RTCC if necessary and loops back to 346. If at 346, there are no more Tx cell clusters to test, then the routine is exited.

In some embodiments, the methods of FIGS. 3C and 3D may be combined to implement a multiple Tx cell to multiple Rx cell scheme. With this scheme, a Tx cell cluster from any of the dies may be part of a path to test to an Rx cell cluster in another die but on the same link.

In an exemplary configuration, the dies may have separate transmit channels to the other dies and may be linked with the receivers over individual one-way channels. A test pattern may be sent from each implicated TTCC to corresponding Rx cells with the patterns compared against expected values and defects logged, as discussed above. For this scheme, the participating TTCCs and RTCCs may be initially programmed together, e.g., through one or more of the TAP interfaces. The tests can then be initiated and run and when completed, the results may be read from the RTCCs or, for example, by an external test apparatus during the testing operation.

FIG. 3E is a flow diagram showing a routine 350 for testing a multi-die package as it is being assembled in accordance with some embodiments. At 352 a count, J, is set to 1. At 354, a second count, K, is set to J+1, and the “K” die (next die) is mounted to the “J” (first or previous) die. At 356, the routine performs defect detection tests for connections between the previous and next dies and makes the results available. At 358, if the detected defects are sufficiently minimal (e.g., in view of redundancy or repairability), then the routine proceeds to 360. Otherwise, the die (die K) is discarded, replaced, and the routine returns to 354 to act on the new “next” die (die K) until one passes, with the routine then proceeding to 360.

At 360, if there is another die to add to the stack, the routine proceeds to 362 where the count (J) is incremented, and the routine loops back to 354 and proceeds as discussed. Once there are no more dies to add to the stack at 360, the routine goes to 364 and proceeds with finalizing assembly of the stack. For example, packaging including protective materials, thermal dissipation components and external access contact structures may be added to the stack. With this approach, costs in terms of yield may be reduced. That is, only individual dies, rather than whole stacks, may be lost.

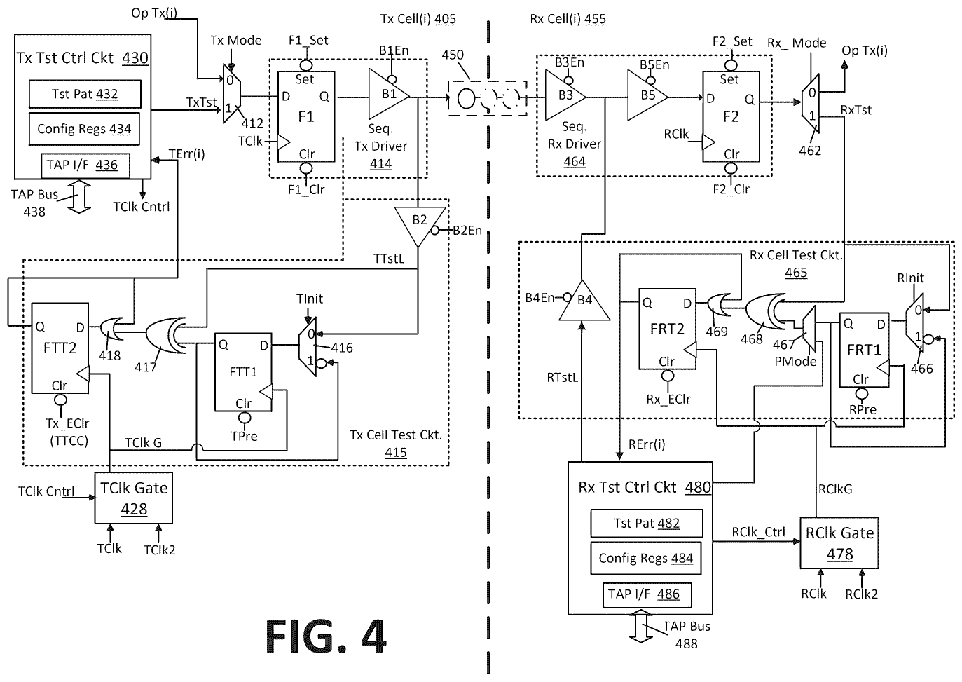

FIG. 4 is a schematic diagram showing a single Tx cell to Rx cell interconnect path in accordance with some embodiments. The diagram shows a single Tx cell (i) to Rx cell (i) path (or lane) coupled together through a channel 450, along with an associated TTCC 430 and RTCC 480.

The depicted Tx cell 405 includes mode mux 412, sequential Tx driver circuit (Tx driver) 414, and Tx cell test circuit 415, coupled together as shown, to the TTCC 430 and channel 450. Also shown is a Tx Clock gate circuit 428 to couple one of two clock inputs, TClk, which is also coupled to the Tx driver, or TClk2, which may be slower than TClk, to the Tx cell test circuit 415.

The TTCC 430 includes a test pattern generation circuit 432, configuration registers 434 and TAP interface circuitry 436 for communication with a TAP 438. The TTCC also has logic circuitry to administer the functions associated with these circuits. The logic circuitry may be implemented with one or more finite state machine circuits (FSMs), micro-controller(s) running code or combinations of the same.

The test pattern generation circuitry may include any suitable circuit(s) to generate a controllable and deterministic test pattern of two or more bits in a stream. For example, it may include circuitry for synthesizing a pattern such as a linear feedback shift register (LFSR) or a toggle generator circuit. Alternatively, or in addition, it may include one or more registers to store one or more programmed patterns or pattern settings for a default or base pattern such as a simple toggle (e.g., ′1010 . . . ) or a hybrid or asymmetric toggle (e.g., ′1001001 . . . ). The associated settings could include pattern cycle periods, clock frequencies and pattern lengths, for example.

The configuration registers include one or more settings to control a test pattern to be generated, or enabled, its characteristics, and whether and how it will be started. For example, it could include a start flag to enable a test, a number of clock cycles value to identify a number of pattern bits to be clocked as part of a test to the Rx cell, a pattern selection value to select a desired pattern option, a Tx cell cluster mask to identify any cells in a TTCC cluster not to be tested, and the like. Regardless, the selected pattern and settings should conform with those applied to the RTCC to match and be aligned with the associated Rx cell's expected pattern. In the depicted embodiment, the Tx driver is clocked from the TClk signal, while the Tx cell test circuit 415 is clocked from a gate controllable clock (TClkG) from gate circuit 428.

The mode mux 412 has operational and test inputs (Op_Tx(i), TxTst), respectively, and an output. Note that the operational input (Op_Tx(i)), which corresponds to operational data when under normal operation, is designated with “(i), indicating that there is a signal line from operational circuitry dedicated to each cell, allowing for data to be driven through the different cells in a cluster at the same time. In contrast, the test signal (TxTst), in the depicted embodiment, is coming out of a switch such as a multiplexer (not shown), e.g., in the TTCC so that less path resources may be used to implement the test circuitry. In some embodiments, when all cells in a cluster are to be tested, the TTCC sequences through the different cells to be tested in a time multiplexed manner.

The transmitter driver 414 includes a flop F1 and a tri-stateable buffer B1 coupled as shown. The F1 flop has an input D that is coupled to the output of mux 412, an output Q, a clock input (TClk), and active-low set (F1_Set) and clear (F1_Clr) inputs. The tri-statable buffer B1 has an input coupled to the F1 flop output (Q), and output coupled to the channel, and a tri-stateable enable input (B1En) that is coupled to the TTCC (as well as to operational control circuitry) for controlling whether the Tx cell is coupled to or decoupled from the channel. The F1 clock input (TClk) receives a transmitter clock that may be provided from the DIC that includes the Tx cell under test. This clock, in some embodiments, may be controlled (e.g., gated, ungated, adjusted) by the TTCC. In operation, when the mode mux (412) is controlled to select the test input and the buffer (B1) is enabled, test data from the TTCC 430 may be clocked through the Tx driver 414 onto the channel 450 for a Tx:Rx path test and also into the Tx cell test circuit 415 for a local Tx cell test.

The Tx cell test circuit 415 includes a tri-stateable buffer B2, a Tx test mux 416. a first Tx test flop (FTT1), an XOR gate circuit 417, an OR gate circuit 418, and a second Tx error flop Ftt2, all coupled as shown. The Tx test buffer B2 has an input coupled to the output of the Tx driver and an output coupled to a first input of the Tx test mux 416 for coupling the Tx driver output to the Tx cell test circuit when the test buffer B2 is enabled, which is controlled by the TTCC. A second input, an inverting input, of the Tx test mux 416 is coupled to an output (Q) of the first Tx test flop (FTT1). An output of the mux 416 is coupled to an input (D) of the flop.

The XOR gate 417 functions as a comparator circuit. It has first and second inputs. The first input is coupled to the output (TTstL) of the Tx test buffer B2, while the second input is coupled to the output of the first Tx test flop, which means it is also coupled to the inverting test mux input. An output of the XOR gate 417 is coupled to a first input of the OR gate 418. A second input of the OR gate 418 is coupled to an output (Q) of the second Tx test flop (FTT2). This output is also coupled to an input (TErr (i)) of the TTCC 430.

In operation, when a signal passes into the test circuit 415 and the test mux 416 is controlled to select the output from buffer B2, the XOR gate 417 receives at its inputs equivalent values, albeit delayed by one TClk cycle. So, if the flops (F1, FTT1) are appropriately preset and if the input to F1 does not change, then the output of XOR gate 417 will be de-asserted (e.g., ′0) in a pre test mode. On the other hand, when the Tx test mux 416 is controlled to select its inverting input, which is coupled to the output of the FTT1 flop, it will generate a toggle pattern at the FTT1 flop output. The XOR compares this toggle pattern against the test pattern coming out of buffer B2. If they are the same, the XOR gate will remain de-asserted but if they are not the same, it asserts, causing the output of the second test flop (FTT2) to assert (e.g., ′1) and remain asserted since this output is coupled with an input of the OR gate 418, making it “sticky.” Thus, if the cell test fails, the result is stored at FTT2 to be read, e.g., by way of a shift operation, by TTCC 430.

The test is initiated by assertion of the “TInit” control input at test mux 416. Before TInit is asserted, however, the outputs of the Tx driver flop (F1) and first test flop (FTT1) should be set to appropriate values to properly set up the test. With the depicted implementation, the flop outputs may both be set to ′1 with the toggle pattern from the TTCC beginning at ′0. In this way, the XOR inputs will be the same if the Tx driver (and Tx cell test circuit for that matter) are working properly.

Turning to the Rx side of the circuit, the Rx cell 455 includes mode demux 462, sequential Rx driver circuit (Rx driver) 464, and Rx cell test circuit 465, coupled together as shown to the RTCC 480 and channel 450. Also shown is an Rx clock gate circuit 478 to couple one of two clock inputs, RClk or RClk2, which may be slower than RClk, to the Rx cell test circuit 465.

The RTCC 480 includes a test pattern circuit 482, configuration registers 484 and TAP interface circuitry 486 for communication with a TAP 488. The RTCC also has logic circuitry to administer the functions associated with these circuits. The logic circuitry may be implemented with one or more finite state machine circuits (FSMs), micro-controller(s) running code or combinations of the same.

The test pattern circuit 482 may include any suitable circuit(s) to provide a controllable test pattern in accordance with an expected pattern for local Rx cell tests and for Tx:Rx path tests. For example, it may include circuitry as described for the pattern circuit 432 in the TTCC 430. The configuration registers 484 include one or more settings to control the pattern, its characteristics and whether and how it will be started. For example, it could include a start flag to enable a test, a number of clock cycles value to identify a number of pattern bits to be expected as part of a test from the Tx cell, a pattern selection value to select a desired pattern option, an Rx cell cluster mask to identify any cells in the RTCC cluster not to be tested, a pass completed flag to indicate if a test has finished, and one or more test results value fields. Regardless, the selected pattern and settings should conform with those applied to the TTCC to match and be aligned with a transmitted pattern for a Tx:Rx path test or for a local Rx cell test.

In some embodiments, when all cells in a cluster are to be tested, the RTCC sequences through the different cells under test in a time multiplexed manner in alignment, e.g., using commonly controlled clock gate and/or multiplexer signals for the TTCC and RTCC circuits.

The mode demux 462 has operational and test outputs (Op_Rx(i), RxTst), respectively, and an input. The receiver driver 464 includes a receiver cell flop F2 and tri-stateable buffers B3, B5 coupled as shown. The F2 flop has an input D that is coupled to the output of buffer B5, an output (Q) coupled to the demux input, a clock input (RClk), and active-low set (F2_Set) and clear (F2_Clr) inputs. The tri-statable buffer B5 has an output coupled to the F2 flop input (D), and an input coupled to the channel through buffer B3. Both B3 and B5 have tri-stateable enable inputs (B3En, B5En) that are coupled to the RTCC (as well as to operational control circuitry) for controlling whether the Rx cell is coupled to or decoupled from the channel. The F2 clock input (RClk) receives a receiver clock that may be provided from the DIC that includes the Rx cell under test. This clock, in some embodiments, may be controlled (e.g., gated, ungated, adjusted) by the RTCC or even by the TTCC. In some embodiments, it is generated, or received, as a forwarded clock from the Tx side, e.g., from the TClk. Even if the RClk is not directly generated from the TClk, it may correspond with the TClk in that they are generated or provided from the same clock source.

In operation, when the mode demux (462) is controlled to select the test input and the buffers (B3, B5) are enabled, test data from the channel 450 may be received through the Rx driver 464 by the RTCC 480 for a Tx:Rx path test or from the RTCC itself by the RTCC through the Rx cell test circuit for a local Rx cell test.

The Rx cell test circuit 465 includes a tri-stateable buffer B4, an Rx test mux 466. a first Rx test flop (FRT1), an XOR gate circuit 467, an OR gate circuit 468, and a second Rx error flop FRT2, all coupled as shown. The Rx test buffer B4 has an input coupled to the output of the Rx driver 464 and an output coupled to a first input of the Rx test mux 466 for coupling the Rx driver output to the Rx cell test circuit when the test buffer B4 is enabled. A second input, an inverting input, of the Rx test mux 466 is coupled to an output (Q) of the first Rx test flop (FRT1). An output of the mux 466 is coupled to an input (D) of the flop. The XOR gate 467 functions as a comparator. It has first and second inputs. Its first input is coupled to the output (RTstL) of the Tx test buffer B4, while the second input is coupled to the output of the first Rx test flop, which means it is also coupled to the inverting test mux input.

An output of the XOR gate 467 is coupled to a first input of the OR gate 468. A second input of the OR gate 468 is coupled to an output (Q) of the second Rx test flop (FRT2). This output is also coupled to an input (RErr(i)) of the RTCC 480.

In operation, when a signal goes into the test circuit 465 and the test mux 466 is controlled to select the output from buffer B4, the XOR gate 467 receives at its inputs equivalent values, albeit delayed by one RClk cycle. Thus, if the flops (F2, FRT1) are appropriately preset and if the input to F2 does not change, then the output of XOR gate 467 will be de-asserted (e.g., ′0) in a pre test mode. On the other hand, when the Rx test mux 466 is controlled to select its inverting input, which is coupled to the output of the FRT1 flop, it will generate a toggle pattern at this FRT1 flop output. The XOR compares this toggle pattern against the test pattern coming out of buffer B4. If they are the same, the XOR gate will remain de-asserted but if they are not the same, it will assert, causing the output of the second test flop (FRT2) to assert (e.g., ′1) and remain asserted since this output is coupled with an input of the OR gate 468, making it “sticky.” Thus, if the cell test fails, the result is stored at FRT2 to be read, e.g., by way of a shift operation, by RTCC 480. The test is initiated by assertion of the “RInit” control input at test mux 466. Before RInit is asserted, however, the outputs of the Rx driver flop (F2) and first test flop (FRT1) may be set to appropriate values to properly set up the test. With the depicted implementation, the flop outputs may both be set to ′1 with the toggle pattern from the RTCC beginning at ′0. In this way, the XOR inputs will be the same if the Rx driver (and Rx cell test circuit, for that matter) are working properly.

For a Tx:Rx path test, a user (e.g., person, systems management controller, or external test apparatus) may initially program the TTCC and RTCC, or they may already be programmed with a desired test pattern, along with appropriate settings. In some embodiments, the RTCC may first be programmed, or initialized, to ensure it is “ready” when the test pattern is initiated by the TTCC. The TTCC start flag, or trigger, may then be asserted, causing the TTCC logic circuit to begin clocking a test pattern to the Rx cell 455 through the channel 450. In some embodiments, the pattern may be transmitted for a programmed number of clock cycles as defined, for example, in the configuration registers 434, 484 and then stop when the TTCC gates off the TClk at clock gate circuit 428. When this happens, the RTCC 480 disables the Rx test cell circuit 465, effectively locking the test result at the output of the second Rx test flop (FRT2). It may store the result in a results register, or it may conduct tests for other cells to be tested. If the latter, it may go back and shift the results from all of the cells in a cluster into a results register of the RTCC or shift them out through a TAP, e.g., into a test apparatus. It may also set a done flag for the cell and de-assert the RInit signal to ready the RTCC for another test.

It should be appreciated that any suitable circuitry could be used for a received test pattern comparison circuit. In the depicted embodiment, test pattern evaluation, timing and alignment may primarily be controlled on the RX side by counting the expected number of received test pattern bits and then locking the second test flop once the count has been reached. In other embodiments, the RTCC could be controlled, directly or indirectly, by the TTCC, e.g., through the TClk when it is tied with the RClk. Other schemes could be used. That is, timing and alignment could be controlled or orchestrated either on the receiver or transmitter sides.

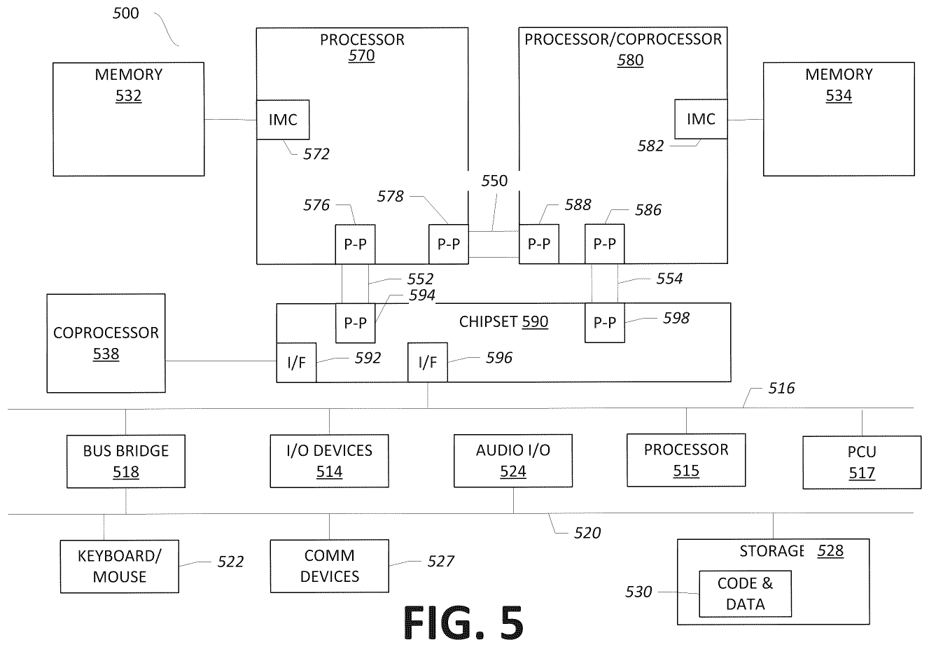

FIG. 5 illustrates an example computing system. Multiprocessor system 500 is an interfaced system and includes a plurality of processors including a first processor 570 and a second processor 580 coupled via an interface 550 such as through die-to-die interconnect links as discussed herein. In some examples, the first processor 570 and the second processor 580 are homogeneous. In some examples, first processor 570 and the second processor 580 are heterogenous. Though the example system 500 is shown to have two processors, the system may have three or more processors, or may be a single processor system. In some examples the computing system is implemented wholly or partially with a multi-chip (or multi-chiplet) module such as with a 3D stack module having link test circuits such as with some of the embodiments described herein.

Processors 570 and 580 are shown including integrated memory controller (IMC) circuitry 572 and 582, respectively. Processor 570 also includes interface circuits 576 and 578, along with core sets. Similarly, second processor 580 includes interface circuits 586 and 588, along with a core set as well. A core set generally refers to one or more compute cores that may or may not be grouped into different clusters, hierarchal groups, or groups of common core types. Cores may be configured differently for performing different functions and/or instructions at different performance and/or power levels. The processors may also include other blocks such as memory and other processing unit engines.

Processors 570, 580 may exchange information via the interface 550 using interface circuits 578, 588. IMCs 572 and 582 couple the processors 570, 580 to respective memories, namely a memory 532 and a memory 534, which may be portions of main memory locally attached to the respective processors.

Processors 570, 580 may each exchange information with a network interface (NW I/F) 590 via individual interfaces 552, 554 using interface circuits 576, 594, 586, 598. The network interface 590 (e.g., one or more of an interconnect, bus, and/or fabric, and in some examples is a chipset) may optionally exchange information with a coprocessor 538 via an interface circuit 592. In some examples, the coprocessor 538 is a special-purpose processor, such as, for example, a high-throughput processor, a network or communication processor, compression engine, graphics processor, general purpose graphics processing unit (GPGPU), neural-network processing unit (NPU), embedded processor, or the like.

A shared cache (not shown) may be included in either processor 570, 580 or outside of both processors, yet connected with the processors via an interface such as P-P interconnect, such that either or both processors' local cache information may be stored in the shared cache if a processor is placed into a low power mode.

Network interface 590 may be coupled to a first interface 516 via interface circuit 596. In some examples, first interface 516 may be an interface such as a Peripheral Component Interconnect (PCI) interconnect, a PCI Express interconnect, or another I/O interconnect. In some examples, first interface 516 is coupled to a power control unit (PCU) 517, which may include circuitry, software, and/or firmware to perform power management operations with regard to the processors 570, 580 and/or co-processor 538. PCU 517 provides control information to one or more voltage regulators (not shown) to cause the voltage regulator(s) to generate the appropriate regulated voltage(s). PCU 517 also provides control information to control the operating voltage generated. In various examples, PCU 517 may include a variety of power management logic units (circuitry) to perform hardware-based power management. Such power management may be wholly processor controlled (e.g., by various processor hardware, and which may be triggered by workload and/or power, thermal or other processor constraints) and/or the power management may be performed responsive to external sources (such as a platform or power management source or system software).

PCU 517 is illustrated as being present as logic separate from the processor 570 and/or processor 580. In other cases, PCU 517 may execute on a given one or more of cores (not shown) of processor 570 or 580. In some cases, PCU 517 may be implemented as a microcontroller (dedicated or general-purpose) or other control logic configured to execute its own dedicated power management code, sometimes referred to as P-code. In yet other examples, power management operations to be performed by PCU 517 may be implemented externally to a processor, such as by way of a separate power management integrated circuit (PMIC) or another component external to the processor. In yet other examples, power management operations to be performed by PCU 517 may be implemented within BIOS or other system software. Along these lines, power management may be performed in concert with other power control units implemented autonomously or semi-autonomously, e.g., as controllers or executing software in cores, clusters, IP blocks and/or in other parts of the overall system.

Various I/O devices 514 may be coupled to first interface 516, along with a bus bridge 518 which couples first interface 516 to a second interface 520. In some examples, one or more additional processor(s) 515, such as coprocessors, high throughput many integrated core (MIC) processors, GPGPUs, accelerators (such as graphics accelerators or digital signal processing (DSP) units), field programmable gate arrays (FPGAs), or any other processor, are coupled to first interface 516. In some examples, second interface 520 may be a low pin count (LPC) interface. Various devices may be coupled to second interface 520 including, for example, a keyboard and/or mouse 522, communication devices 527 and storage circuitry 528. Storage circuitry 528 may be one or more non-transitory machine-readable storage media as described below, such as a disk drive or other mass storage device which may include instructions/code and data 530 and may implement the storage in some examples. Further, an audio I/O 524 may be coupled to second interface 520. Note that other architectures than the point-to-point architecture described above are possible. For example, instead of the point-to-point architecture, a system such as multiprocessor system 500 may implement a multi-drop interface or other such architecture.

Processor cores may be implemented in different ways, for different purposes, and in different processors. For instance, implementations of such cores may include: 1) a general purpose in-order core intended for general-purpose computing; 2) a high-performance general purpose out-of-order core intended for general-purpose computing; 3) a special purpose core intended primarily for graphics and/or scientific (throughput) computing. Implementations of different processors may include: 1) a CPU including one or more general purpose in-order cores intended for general-purpose computing and/or one or more general purpose out-of-order cores intended for general-purpose computing; and 2) a coprocessor including one or more special purpose cores intended primarily for graphics and/or scientific (throughput) computing. Such different processors lead to different computer system architectures, which may include: 1) the coprocessor on a separate chip from the CPU; 2) the coprocessor on a separate die in the same package as a CPU; 3) the coprocessor on the same die as a CPU (in which case, such a coprocessor is sometimes referred to as special purpose logic, such as integrated graphics and/or scientific (throughput) logic, or as special purpose cores); and 4) a system on a chip (SoC) that may be included on the same die as the described CPU (sometimes referred to as the application core(s) or application processor(s)), the above described coprocessor, and additional functionality. Example core architectures are described next, followed by descriptions of example processors and computer architectures.

Illustrative examples of the technologies disclosed herein are provided below. An embodiment of the technologies may include any one or more, and any compatible combination of, the examples described below.

Example 1 is an apparatus that has first, second and third dies. The first die has a first transmitter test control circuit (TTCC) and a plurality of first transmitter (Tx) cell circuits coupled to the first TTCC. The second die is connected to the first die through a plurality of first contacts, and the second die has a first receiver test control circuit (RTCC) and a plurality of first receiver (Rx) cell circuits coupled to the first RTCC. The first Tx cell circuits and first Rx cell circuits are coupled to the first contacts. The third die is connected to the second die through a plurality of second contacts. The third die has a second receiver test control circuit (RTCC) and a plurality of second receiver (Rx) cell circuits coupled to the second RTCC and to the second contacts. The first die has a first test access port (TAP) to control the first TTCC to perform defect detection tests on first paths from the first Tx cell circuits to the first Rx cell circuits through the first contacts and on second paths from the first Tx cell circuits to the second Rx cell circuits through the first and second contacts.

Example 2 includes the subject matter of example 1, and wherein the second die has a second TAP to control the first RTCC to perform the defect detection tests on the first paths.

Example 3 includes the subject matter of any of examples 1 and 2, and wherein the second die has a plurality of second Tx cell circuits and a second TTCC to control defect detection tests on third paths from the second Tx cell circuits through the second contacts to the second Rx cell circuits.

Example 4 includes the subject matter of any of examples 1-3, and wherein the second TAP is to control the second TTCC to perform the defect detection tests on the third paths.

Example 5 includes the subject matter of any of examples 1-4, and wherein the third die has a third TAP to control the second RTCC to perform the defect detection tests on the Tx:Rx paths from the first Tx cell circuits to the second Rx cell circuits.

Example 6 includes the subject matter of any of examples 1-5, and wherein the first die is a processing die, the second and third dies are memory dies, and the first and second paths are unidirectional paths to write data from the first die to the second and third dies.

Example 7 includes the subject matter of any of examples 1-6, and wherein the first and second pluralities of contacts are hybrid bonded contacts.

Example 8 includes the subject matter of any of examples 1-7, and wherein the first Tx cell circuits each have a transmitter (Tx) cell test circuit to perform a local Tx cell test.

Example 9 includes the subject matter of any of examples 1-8, and wherein the Tx cell test circuits each have a test pattern comparator circuit to compare a test pattern driven through the Tx cell circuit with an expected test pattern.

Example 10 includes the subject matter of any of examples 1-9, and wherein the Tx cell test circuits have a toggle generator circuit to generate the expected test pattern.

Example 11 includes the subject matter of any of examples 1-10, and wherein the first Rx cell circuits have first receiver (Rx) cell test circuits to test the first paths, and the second Rx cell circuits have second Rx cell test circuits to test the second paths.

Example 12 includes the subject matter of any of examples 1-11, and wherein the second Rx cell test circuits have test pattern comparator circuits to compare a test pattern driven through the first and second contacts with an expected test pattern.

Example 13 is an apparatus that includes a plurality of dies and a conductive channel. The plurality of dies are mounted one upon another. Each die includes (i) a transmitter (Tx) cell circuit tri-statably coupled to the conductive channel, (ii) a receiver (Rx) cell circuit tri-statably coupled to the conductive channel, (iii) a transmitter test control circuit (TTCC) coupled to the Tx cell circuit, and (iv) a receiver test control circuit (RTCC) coupled to the Rx cell circuit. The TTCCs and RTCCs are controllable through at least one test access port (TAP) to test Tx:Rx paths through the conductive channel between the Tx cell circuit from a first of the plurality of dies to the Rx cell circuits in two or more different dies of the plurality of dies.

Example 14 includes the subject matter of example 13, and wherein the plurality of dies are mounted together through hybrid bonding in a stack configuration.

Example 15 includes the subject matter of any of examples 13-14, and wherein the conductive channel includes hybrid contact connections between pairs of mounted together dies.

Example 16 includes the subject matter of any of examples 13-15, and wherein the Rx cell circuits from the two or more different dies may be active at the same time on the conductive channel to receive a common test pattern.

Example 17 includes the subject matter of any of examples 13-16, and wherein each die of the plurality of dies has a separate test access port (TAP) coupled to the TTCC and RTCC within the die.

Example 18 includes the subject matter of any of examples 13-17, and wherein the first die has a TAP that is coupled to the TTCC and RTCC in each of the plurality of dies.

Example 19 includes the subject matter of any of examples 13-18, and wherein the Tx cell circuits and Rx cell circuits in the plurality of dies are part of a link having single-ended Tx cell circuit to Rx cell circuit interconnections.

Example 20 includes the subject matter of any of examples 13-19, and wherein the link is a unidirectional link.

Example 21 includes the subject matter of any of examples 13-20, and wherein the Tx cell circuit to Rx cell circuit interconnections include a sequential transmitter (Tx) driver circuit coupled through the conductive channel to a sequential receiver (Rx) driver circuit.

Example 22 includes the subject matter of any of examples 13-21, and wherein the sequential Tx driver circuit and sequential Rx driver circuit in a common interconnection have clock inputs to a common clock source.

Example 23 includes the subject matter of any of examples 13-22, and wherein the Tx cell circuits have a transmitter (Tx) cell test circuit to perform a local Tx cell test.

Example 24 includes the subject matter of any of examples 13-23, and wherein the Tx cell test circuit has a test pattern comparator circuit to compare a test pattern driven through the Tx cell circuit with an expected test pattern.

Example 25 includes the subject matter of any of examples 13-24, and wherein the Tx cell test circuit has a toggle generator circuit to generate the expected test pattern.

Example 26 includes the subject matter of any of examples 13-25, and wherein the Rx cell circuits have a receiver (Rx) cell test circuit to test the Tx:Rx paths.

Example 27 includes the subject matter of any of examples 13-26, and wherein the Rx cell test circuit has a test pattern comparator circuit to compare a test pattern driven through the conductive channel with an expected test pattern.

Example 28 includes the subject matter of any of examples 13-27, and wherein the Rx cell test circuit has a toggle generator circuit to generate the expected test pattern.

Example 29 includes the subject matter of any of examples 13-28, and wherein the RTCC is to generate the expected test pattern.

Example 30 includes the subject matter of any of examples 13-29, and wherein the RTCC is to control the Rx cell test circuit to save a comparison result in response to a programmed number of test pattern clock cycles.

Example 31 is a processing system that includes a processing die and first and second memory dies. The processing die has a first transmitter test control circuit (TTCC) and a plurality of first transmitter (Tx) cell circuits coupled to the first TTCC. The first memory die is connected to the processing die through a plurality of first hybrid bonded contact connections. The first memory die has a first receiver test control circuit (RTCC) and a plurality of first receiver (Rx) cell circuits coupled to the first RTCC, wherein the first Tx cell circuits and first Rx cell circuits are coupled to the first hybrid bonded contact connections. The second memory die is connected to the first memory die through a plurality of second hybrid bonded contact connections. The second memory die has a second receiver test control circuit (RTCC) and a plurality of second receiver (Rx) cell circuits coupled to the second RTCC and to the second contacts, wherein the processing die has a first test access port (TAP) to control the first TTCC to perform defect detection tests on first paths from the first Tx cell circuits to the first Rx cell circuits through the first hybrid bonded contact connections and on second paths from the first Tx cell circuits to the second Rx cell circuits through the first and second hybrid bonded contact connections.

Example 32 includes the subject matter of example 31, and wherein the first memory die has a second TAP to control the first RTCC to perform the defect detection tests on the first paths.

Example 33 includes the subject matter of any of examples 31-32, and wherein the first memory die has a plurality of second Tx cell circuits and a second TTCC to control defect detection tests on third paths from the second Tx cell circuits through the second hybrid bonded contact connections to the second Rx cell circuits.

Example 34 includes the subject matter of any of examples 31-33, and wherein the second TAP is to control the second TTCC to perform the defect detection tests on the third paths.

Example 35 includes the subject matter of any of examples 31-34, and wherein the second memory die has a third TAP to control the second RTCC to perform the defect detection tests on the Tx:Rx paths from the first Tx cell circuits to the second Rx cell circuits.

Example 36 includes the subject matter of any of examples 31-35, and wherein the processing die is an artificial intelligence (AI) accelerator, and the first and second paths are unidirectional paths to write data from the AI accelerator die to the first and second memory dies.

Example 37 includes the subject matter of any of examples 31-36, and wherein the first Tx cell circuits each have a transmitter (Tx) cell test circuit to perform a local Tx cell test

Example 38 is a method that includes (i) connecting a first die having a first die interconnect circuit (DIC) through a plurality of first contacts to a second die having a second DIC; (ii) performing a defect detection test on a first Tx:Rx path through the first contacts between the first and second DICs; (iii) based on whether the defect detection test indicates the first Tx:Rx path is operable, connecting a third die having a third DIC through a plurality of second contacts to the second DIC; and (iv) performing the defect detection test on a second Tx:Rx path through the first and second contacts between the first and third DICs.

Example 39 includes the subject matter of example 38, and wherein the first and second contacts are part of a channel cluster, the first, second, and third DICs being tri-statably connected to the channel cluster.

Example 40 includes the subject matter of any of examples 38-39, and wherein the first, second and third dies each have a test access port to control the performance of a defect detection test.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “circuit” or “module” may refer to one or more passive and/or active components that are arranged to cooperate with one another to provide a desired function. It should be appreciated that different circuits or modules may consist of separate components, they may include both distinct and shared components, or they may consist of the same components. For example, A controller circuit may be a first circuit for performing a first function, and at the same time, it may be a second controller circuit for performing a second function, related or not related to the first function.

The meaning of “in” includes “in” and “on” unless expressly distinguished for a specific description.

The terms “substantially,” “close,” “approximately,” “near,” and “about,” unless otherwise indicated, generally refer to being within +/−10% of a target value.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

It is pointed out that those elements of the figures having the same reference numbers (or names) as the elements of any other figure can operate or function in any manner similar to that described but are not limited to such.

For purposes of the embodiments, unless expressly described differently, the transistors in various circuits and logic blocks described herein may be implemented with any suitable transistor type such as field effect transistors (FETs) or bipolar type transistors. FET transistor types may include but are not limited to metal oxide semiconductor (MOS) type FETs such as tri-gate, FinFET, and gate all around (GAA) FET transistors, as well as tunneling FET (TFET) transistors, ferroelectric FET (FeFET) transistors, or other transistor device types such as carbon nanotubes or spintronic devices.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are dependent upon the platform within which the present disclosure is to be implemented.

As defined herein, the term “computer readable storage medium” means a storage medium that contains or stores program code for use by or in connection with an instruction execution system, apparatus, or device. As defined herein, a “computer readable storage medium” is not a transitory, propagating signal per se. A computer readable storage medium may be, but is not limited to, an electronic storage device, a magnetic storage device, an optical storage device, an electromagnetic storage device, a semiconductor storage device, or any suitable combination of the foregoing. Memory elements, as described herein, are examples of a computer readable storage medium.

As defined herein, the term “if” means “when” or “upon” or “in response to” or “responsive to,” depending upon the context. Thus, the phrase “if it is determined” or “if [a stated condition or event] is detected” may be construed to mean “upon determining” or “in response to determining” or “upon detecting [the stated condition or event]” or “in response to detecting [the stated condition or event]” or “responsive to detecting [the stated condition or event]” depending on the context. As defined herein, the term “responsive to” means responding or reacting readily to an action or event. Thus, if a second action is performed “responsive to” a first action, there is a causal relationship between an occurrence of the first action and an occurrence of the second action. The term “responsive to” indicates the causal relationship.

As defined herein, the term “processor” or “processing system” means at least one hardware circuit configured to carry out instructions contained in program code. The hardware circuit may be implemented with one or more integrated circuits. Examples of a processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, an accelerator, a graphics processing unit (GPU), a controller, and so forth.

It should be appreciated that a processor or processor system may be implemented in various different manners. For example, it may be implemented on a single die, multiple dies (dielets, chiplets), one or more dies in a common package, or one or more dies in multiple packages. Along these lines, some of these blocks may be located separately on different dies or together on two or more different dies.

While the flow diagrams in the figures show a particular order of operations performed by certain embodiments of the invention, it should be understood that such order is exemplary (e.g., alternative embodiments may perform the operations in a different order, combine certain operations, overlap certain operations, etc.).

While the invention has been described in terms of several embodiments, those skilled in the art will recognize that the invention is not limited to the embodiments described, can be practiced with modification and alteration within the spirit and scope of the appended claims. The description is thus to be regarded as illustrative instead of limiting.

What is claimed is:

1. An apparatus, comprising:
a first die having a first transmitter test control circuit (TTCC) and a plurality of first transmitter (Tx) cell circuits coupled to the first TTCC;
a second die connected to the first die through a plurality of first contacts, the second die having a first receiver test control circuit (RTCC) and a plurality of first receiver (Rx) cell circuits coupled to the first RTCC, wherein the first Tx cell circuits and first Rx cell circuits are coupled to the first contacts; and
a third die connected to the second die through a plurality of second contacts, the third die having a second receiver test control circuit (RTCC) and a plurality of second receiver (Rx) cell circuits coupled to the second RTCC and to the second contacts, wherein the first die has a first test access port (TAP) to control the first TTCC to perform defect detection tests on first paths from the first Tx cell circuits to the first Rx cell circuits through the first contacts and on second paths from the first Tx cell circuits to the second Rx cell circuits through the first and second contacts.

2. The apparatus of claim 1, wherein the second die has a second TAP to control the first RTCC to perform the defect detection tests on the first paths.

3. The apparatus of claim 2, wherein the second die has a plurality of second Tx cell circuits and a second TTCC to control defect detection tests on third paths from the second Tx cell circuits through the second contacts to the second Rx cell circuits.

4. The apparatus of claim 2, wherein the second TAP is to control the second TTCC to perform the defect detection tests on the third paths.

5. The apparatus of claim 2, wherein the third die has a third TAP to control the second RTCC to perform the defect detection tests on the second Tx:Rx paths from the first Tx cell circuits to the second Rx cell circuits.

6. The apparatus of claim 1, wherein the first and second contacts are hybrid bonded contacts.

7. The apparatus of claim 1, wherein the first Tx cell circuits each have a transmitter (Tx) cell test circuit to perform a local Tx cell test.

8. The apparatus of claim 7, wherein the Tx cell test circuits each have a test pattern comparator circuit to compare a test pattern driven through the Tx cell circuit with an expected test pattern.

9. The apparatus of claim 7, wherein the Tx cell test circuits have a toggle generator circuit to generate the expected test pattern.

10. The apparatus of claim 1, wherein the first Rx cell circuits have first receiver (Rx) cell test circuits to test the first paths, and the second Rx cell circuits have second Rx cell test circuits to test the second paths.

11. The apparatus of claim 10, wherein the second Rx cell test circuits have test pattern comparator circuits to compare a test pattern driven through the first and second contacts with an expected test pattern.

12. An apparatus, comprising:
a plurality of dies mounted one upon another;
a conductive channel, wherein each die has:
a transmitter (Tx) cell circuit tri-statably coupled to the conductive channel,
a receiver (Rx) cell circuit tri-statably coupled to the conductive channel,
a transmitter test control circuit (TTCC) coupled to the Tx cell circuit, and
a receiver test control circuit (RTCC) coupled to the Rx cell circuit; and
wherein the TTCCs and RTCCs are controllable through at least one test access port (TAP) to test Tx:Rx paths through the conductive channel between the Tx cell circuit from a first of the plurality of dies to the Rx cell circuits in two or more different dies of the plurality of dies.

13. The apparatus of claim 12, wherein the plurality of dies are mounted together through hybrid bonding in a stack configuration.

14. The apparatus of claim 12, wherein the Rx cell circuits from the two or more different dies may be active at the same time on the conductive channel to receive a common test pattern.

15. The apparatus of claim 12, wherein each die of the plurality of dies has a separate test access port (TAP) coupled to the TTCC and RTCC within the die.

16. The apparatus of claim 12, wherein the Tx cell circuits each have a transmitter (Tx) cell test circuit to perform a local Tx cell test.

17. The apparatus of claim 12, wherein the RTCC is to control an Rx cell test circuit in the Rx cell circuits to save a comparison result in response to a programmed number of test pattern clock cycles.

18. A processing system, comprising:
a processor die having a first transmitter test control circuit (TTCC) and a plurality of first transmitter (Tx) cell circuits coupled to the first TTCC;
a first memory die connected to the processor die through a plurality of first hybrid bonded contact connections, the first memory die having a first receiver test control circuit (RTCC) and a plurality of first receiver (Rx) cell circuits coupled to the first RTCC, wherein the first Tx cell circuits and first Rx cell circuits are coupled to the first hybrid bonded contact connections; and
a second memory die connected to the first memory die through a plurality of second hybrid bonded contact connections, the second memory die having a second receiver test control circuit (RTCC) and a plurality of second receiver (Rx) cell circuits coupled to the second RTCC and to the second contacts, wherein the processor die has a first test access port (TAP) to control the first TTCC to perform defect detection tests on first paths from the first Tx cell circuits to the first Rx cell circuits through the first hybrid bonded contact connections and on second paths from the first Tx cell circuits to the second Rx cell circuits through the first and second hybrid bonded contact connections.

19. The system of claim 18, wherein the first memory die has a second TAP to control the first RTCC to perform the defect detection tests on the first paths.

20. The apparatus of claim 19, wherein the first memory die has a plurality of second Tx cell circuits and a second TTCC to control defect detection tests on third paths from the second Tx cell circuits through the second hybrid bonded contact connections to the second Rx cell circuits.
